(19) United States
(12) Patent Application Publication
(10) Pub. No.: US 2008/0020507 A1
(43) Pub. Date: Jan. 24, 2008

(54) Method for manufacturing semiconductor integrated circuit device

(75) Inventor: Yoji Nomura, Mizuho-shi (JP)

Correspondence Address: OLIFF & BERRIDGE, PLC, P.O. BOX 320850, ALEXANDRIA, VA, 22320-4850, US

(73) Assignees: SANYO ELECTRIC CO., LTD., Moriguchi-shi (JP); SANYO SEMICONDUCTOR CO., LTD., Ora-gun (JP)

(21) Appl. No.: 11/826,422

(22) Filed: Jul. 16, 2007

(30) Foreign Application Priority Data
Jul. 20, 2006 (JP) 2006-198586

(51) Int. Cl. H01L 21/00

(52) U.S. Cl. 438/98; 257/E21.507

(57) ABSTRACT

Due to a difference in a film thickness generated in structure layers located on top of a light receiver, a bottom surface of an open part does not flatten and an amount of incident light within a surface of the light receiver becomes nonuniform. A flat layer is formed by using a damascene process to form a first metal interlayer or by polishing using CMP an insulation film stacked after the first metal layer is formed. As a result, the insulation film stacked on the light receiver is also formed evenly. Thus, when an inside of the light receiver is opened by etching, the bottom surface of the open part can be formed evenly.

### CROSS-REFERENCE TO RELATED APPLICATIONS

The priority application number JP2006-198586 upon which this patent application is based is hereby incorporated by the reference.

### BACKGROUND OF THE INVENTION

1. Field of the Invention

The present invention relates to a semiconductor integrated circuit device in which an integrated circuit is formed on a semiconductor substrate which includes a light receiver and, more particularly, to a method for manufacturing a semiconductor integrated circuit device in which an open part is formed by etching an interlayer insulation film stacked on a substrate.

2. Description of the Related Art

In recent years, as information recording media, optical disks such as CDs (Compact Disks) and DVDs (Digital Versatile Disks) have become predominant. A playback device of the optical disks replays recorded data based on detection by a photodetector of a change in intensity of reflected light of laser light irradiated along a track of the optical disk.

FIG. 1 is a schematic plan view of a conventional photodetector 10.

FIG. 2 is a schematic sectional view of a light receiver 11 and a wiring structure 12 taken along the line A-A′ of FIG. 1 and vertical to a semiconductor substrate.

The photodetector 10, which detects reflected light, has the light receiver 11 buried in a surface of the semiconductor substrate 14. The light receiver 11 includes a PIN photodiode (PD) diffusion layer 34 divided into 2.times.2=4 partitions. The PD diffusion layer 34 is formed as, for instance, a cathode area where an N-type impurity is diffused at a high concentration. Furthermore, the PD diffusion layer 34 is separated by a separative diffusion layer 33. The separative diffusion layer 33 is formed as, for instance, an anode area where a P-type impurity is diffused at a high concentration on the surface of the semiconductor substrate 14. A faint photoelectric conversion signal is generated by inputting reflected light of laser light into the light receiver 11, and this signal is amplified by an amplifier formed in an adjacent area and is output to a signal processing circuit in a latter stage.

The photodetector 10 has a first interlayer insulation film 16, a first metal layer 17, a second interlayer insulation film 18, a second metal layer 19 and a third interlayer insulation film 20 stacked in sequence on the semiconductor substrate 14. The first metal layer 17 and the second metal layer 19, respectively, are formed of aluminum (Al), etc. and patterned by using a photolithographic technique. By patterning, a wiring structure 12, and a signal line 13A and a voltage application line 13B which are connected to the wiring structure 12 are formed in the first metal layer 17. As a result, the separative diffusion layer 33 is set at a fixed electric potential by the voltage application line 13B through the wiring structure 12. On the other hand, a photoelectric conversion signal generated at each PD diffusion layer 34 is also taken out by the signal line 13A through the wiring structure 12.

In the above-described configuration, in order to secure frequency characteristics of the photoelectric conversion signal and to suppress noise superposition, both each PD diffusion layer 34 and the separative diffusion layer 33 are required to be electrically connected to the signal line 13A and the voltage application line 13B respectively so as to be low resistance. Therefore, it is necessary that the wiring structure 12 is electrically connected to each diffusion layer through as many contact holes as possible. Thus, as shown in FIG. 1, the wiring structure 12 is arranged so as to encompass the light receiver 11.

After the metal layers and the interlayer insulation films are stacked, an open part 15 is formed by etching interlayer insulation films, etc. stacked on the light receiver 11 in order to enhance incident efficiency of light to the light receiver 11. The open part 15 is opened so as to be a similar shape, which is one size smaller, to the one that the wiring structure 12 forms.

FIG. 3 is a perspective view of the light receiver 11 and the wiring structure 12. As shown in FIG. 3, the wiring structure 12 is arranged around the light receiver on the semiconductor substrate.

After the wiring structure 12 is formed around the light receiver 11, an insulation film is formed. The insulation film is formed by using materials such as SOG (Spin on Glass), BPSG (Boro-Phospho Silicate Glass) and TEOS (Tetraethyl Orthosilicate).

After the insulation film is formed, the insulation film, etc. stacked on the light receiver 11 is removed by anisotropic etching and the open part 15 is formed. Since the wiring structure 12 is thick, the surface of the insulation film stacked on the wiring structure 12 does not flatten and becomes a concavo-convex shape. Additionally, when an insulation film, etc. is further stacked in sequence on the insulation film whose surface is formed into a concavo-convex shape, the surface of a film formed on top also does not flatten and becomes a concavo-convex shape. Thus, when the open part 15 is formed by etching the insulation film, etc. stacked on the light receiver 11, a bottom surface of the open part 15 has a form which the surface form of the film formed on the top is transcribed as it is before etching. That is, the bottom surface of the open part 15 is not also formed evenly.

Thus, when the bottom surface of the open part 15 is not formed evenly, the incident efficiency within the surface of the light receiver 11 is not equalized. Furthermore, when the uneven portion of the bottom surface of the open part 15 reflects the light, a photoelectric conversion of the photodetector may be adversely affected.

### [Patent Reference 1] JP 2001-60713 A

### SUMMARY OF THE INVENTION

The present invention provides a method for manufacturing a semiconductor integrated circuit device comprising:

on a semiconductor substrate which includes a light receiver,

forming a first insulation film on the semiconductor substrate;

forming a wiring structure around the light receiver on the first insulation film by a damascene process;

forming a second insulation film on the wiring structure;

and opening the second insulation film formed on the light receiver by etching.

The present invention provides a method for manufacturing a semiconductor integrated circuit device comprising:

on a semiconductor substrate which includes a light receiver,

forming a first insulation film on the semiconductor substrate;

forming a wiring structure around the light receiver on the first insulation film;

forming a second insulation film on the wiring structure;

flattening a surface of the second insulation film;

forming a third insulation film on the second insulation film;

and opening the third insulation film formed on the light receiver by etching.

### BRIEF DESCRIPTION OF THE DRAWINGS

FIG. 1 is a schematic plan view of a conventional photodetector;

FIG. 2 is a schematic sectional view of a conventional photodetector;

FIG. 3 is a perspective view showing an arrangement of a light receiver and a wiring structure;

FIGS. 4A-4D show formation processes of a photodetector in accordance with a first embodiment of the present invention; and

FIGS. 5A-5F show formation processes of a photodetector in accordance with a second embodiment of the present invention.

### DETAILED DESCRIPTION OF THE PREFERRED EMBODIMENT

In what follows, embodiments of the present invention will be described with reference to the drawings.

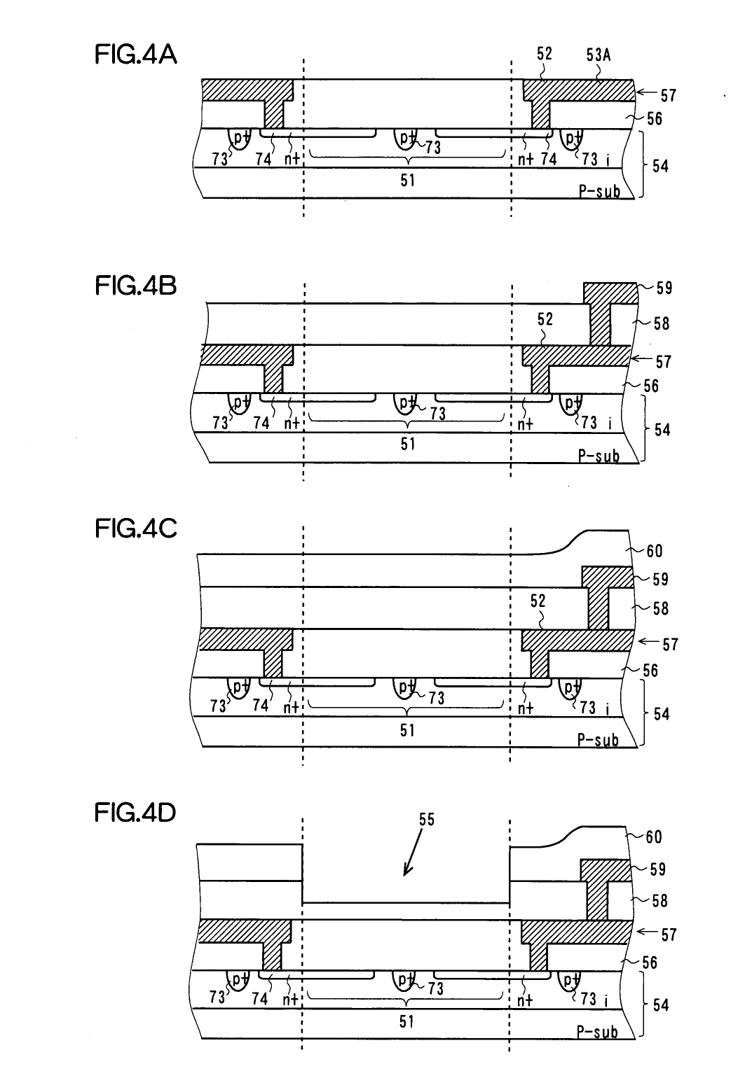

FIGS. 4A-4D are views showing formation processes of a photodetector in accordance with a first embodiment of the present invention.

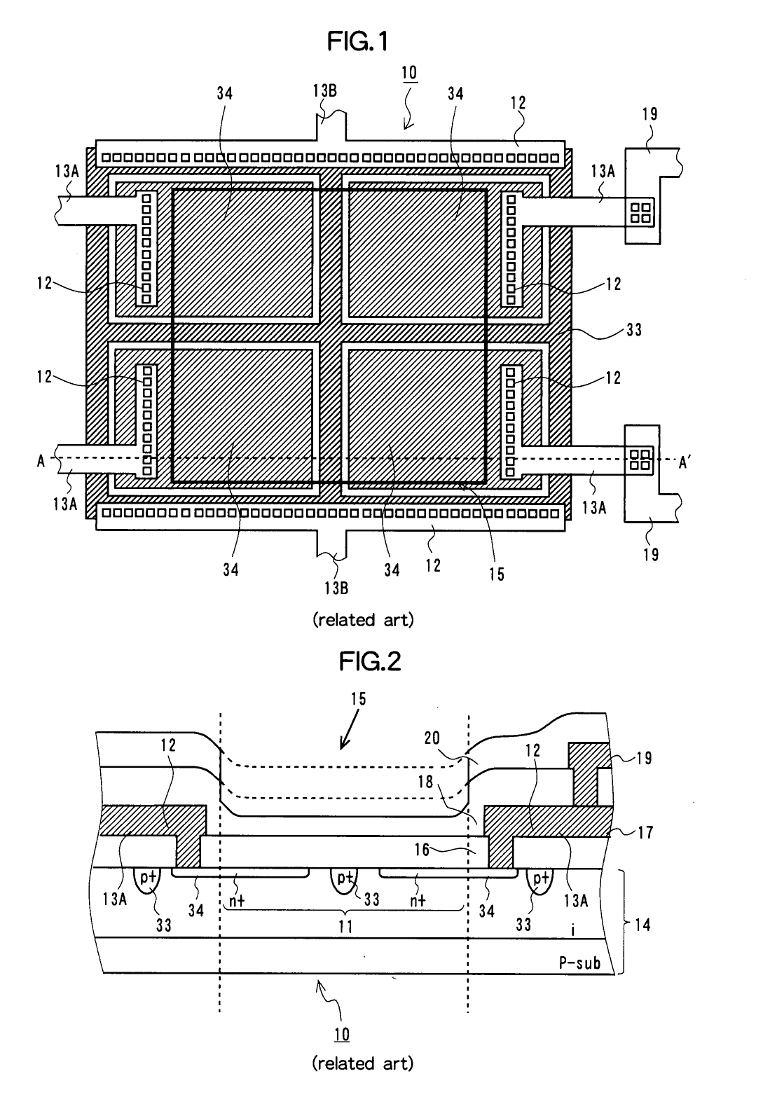

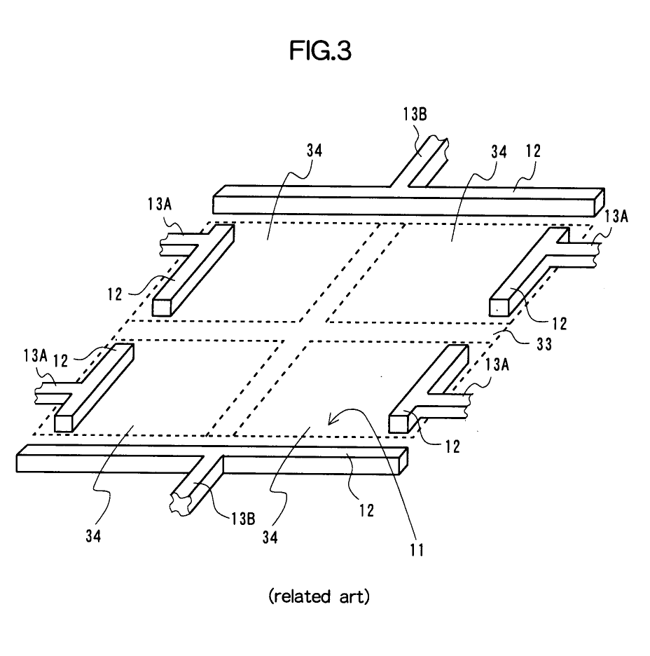

FIGS. 4A-4D are sectional views taken along the line A-A′ of FIG. 1 and vertical to a semiconductor substrate. The planar shape of the photodetector in this embodiment is the same as that in FIG. 1.

Firstly, a first insulation film 56 is formed on a semiconductor substrate 54 where a light receiver 51 is formed on the surface and further, a first metal layer 57 is formed by a damascene process (FIG. 4A). The first metal layer 57 is formed of aluminum (Al), tungsten (W), etc. The surfaces of the first insulation film 56 and the first metal layer 57 are formed evenly by using the damascene process and a wiring structure 52, and a signal line 53A and a voltage application line (not shown) which are connected to the wiring structure 52 are formed in the first metal layer 57. The wiring structure 52 is formed around the light receiver 51. Furthermore, the wiring structure 52 is connected electrically to a separative diffusion layer 73 and each PD diffusion layer 74 through a plurality of contact holes. As a result, the separative diffusion layer 73 is set at a fixed electric potential by the voltage application line through the wiring structure 52. For instance, a ground potential is applied to the separative diffusion layer 73. Furthermore, a photoelectric conversion signal generated by inputting reflected light into each PD diffusion layer 74 is taken out by the signal line 53A through the wiring structure 52.

After the first metal layer 57 is formed, a second insulation film 58 and a second metal layer 59 are formed (FIG. 4B). Since the second insulation film 58 is stacked on the first insulation film 56 and the first metal layer 57 whose surfaces are formed evenly, a surface of the second insulation film 58 is also formed evenly. Then, the second metal layer 59 is formed at a position farther from the light receiver 51 than the wiring structure 52 and connected to the first metal layer 57 through a contact hole. In this embodiment, after a metal layer is stacked on the second insulation film 58, the second metal layer 59 is formed by patterning this metal layer by using the photolithographic technique. However, the damascene process and other methods can also be used.

After the second metal layer 59 is formed, a third insulation film 60 is formed (FIG. 4C). Since the second metal layer 59 is formed at a position farther from the light receiver 51 than the wiring structure 52, a flatness of the third insulation film 60 formed on the light receiver 51 is not affected. Thus, the third insulation film 60 on the light receiver 51 is formed evenly.

After each metal layer and each insulation film are stacked, an open part 55 is formed (FIG. 4D) by etching each insulation film stacked on the light receiver 51 in order to enhance incident efficiency of reflected light to the light receiver 51. Since the surface of the third insulation film 60 stacked on the light receiver 51 is formed evenly, a bottom surface of the open part 55 is also formed evenly. This is because that the bottom surface of the open part 55 has a form which the surface form of the film formed on the top is transcribed as it is before etching.

As described in this embodiment, by forming the first metal layer 57 by using the damascene process, a formation of the wiring structure 52 and flattening of the insulation film on the light receiver 51 can be realized in the identical process. Furthermore, each insulation film stacked on the light receiver 51 can be stacked so as to be flat and the bottom surface of the open part 55 can be flattened. As a result, the incident efficiency within the surface of the light receiver 51 can be equalized. Furthermore, an adverse affect on the photoelectric conversion of the photodetector generated due to light reflected by an uneven portion of the bottom surface of the open part 55 can be suppressed.

Next, a second embodiment will be described below.

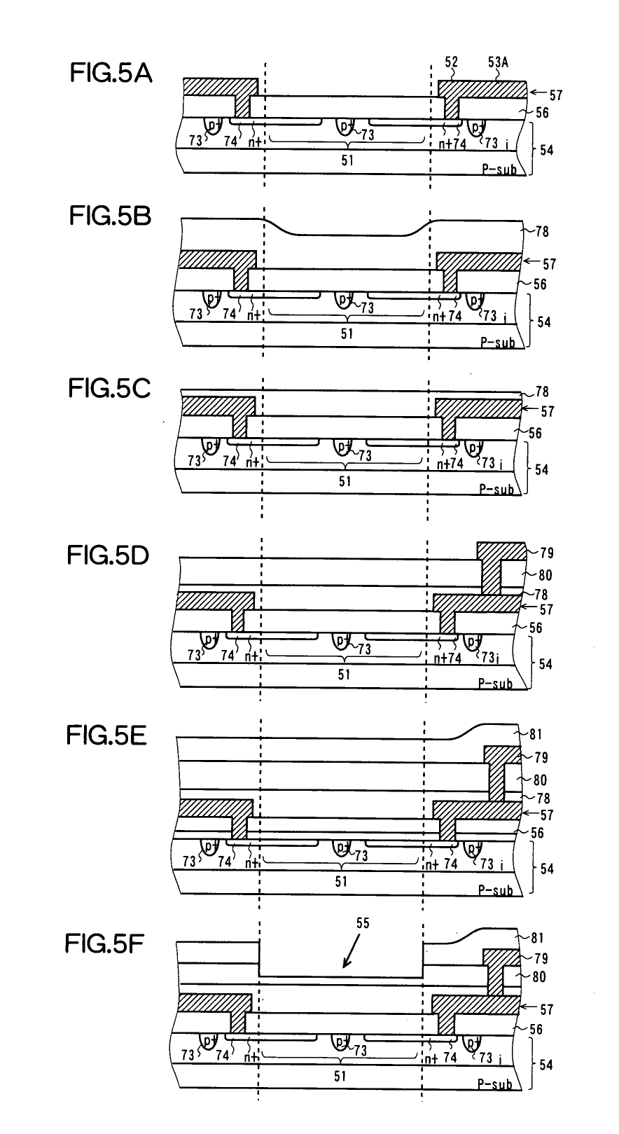

FIGS. 5A-5F are views showing formation processes of a photodetector in accordance with a second embodiment of the present invention.

FIG. 5A-5F are sectional views taken along the line A-A′ of FIG. 1 and vertical to a semiconductor substrate. The planar shape of the photodetector in this embodiment is the same as that in FIG. 1.

Firstly, the first insulation film 56 and the first metal layer 57 are stacked in sequence on the semiconductor substrate 54 where the light receiver 51 is formed on the surface (FIG. 5A). The first metal layer 57 is formed of aluminum (Al), etc. and patterned by using a photolithographic technique. The wiring structure 52, and a signal line 53A and a voltage application line (not shown) which are connected to the wiring structure 52 are formed in the first metal layer 57 by patterning. The wiring structure 52 is formed around the light receiver. As a result, the separative diffusion layer 73 is set at a fixed electric potential by the voltage application line through the wiring structure 52. For instance, a ground potential is applied to the separative diffusion layer 73. Furthermore, a photoelectric conversion signal generated by inputting reflected light into each PD diffusion layer 74 is taken out by the signal line 53A through the wiring structure 52.

After the first metal layer 57 is formed, a second insulation film 78 is stacked (FIG. 5B). Since the first metal layer 57 is thick, a surface of the second insulation film 78 does not become flat.

After the second insulation film 78 is stacked, the surface of the second insulation film 78 is formed evenly by using CMP (Chemical Mechanical Polishing) and so on (FIG. 5C).

A third insulation film 80 and a second metal layer 79 are formed (FIG. 5D) on a layer which the first metal layer 57 and the second insulation film 78 are formed. Since the third insulation film 80 is stacked on the second insulation film 78 whose surface is formed evenly, the surface of the third insulation film 80 is also formed evenly. When the second insulation film 78 is thick enough, it is not necessary to stack the third insulation film 80. The second metal layer 79 is formed at a position farther from the light receiver 51 than the wiring structure 52 and the second metal layer 79 and the first metal layer 57 are connected through a contact hole. In this embodiment, after a metal layer is stacked on the third insulation film 80, the second metal layer 79 is formed by patterning this metal layer by using the photolithographic technique. However, the damascene process and other methods can also be used.

After the second metal layer 78 is formed, a fourth insulation film 81 is formed (FIG. 5E). Since the second metal layer 78 is formed at a position farther from the light receiver 51 than the wiring structure 52, the flatness of the fourth insulation film 81 formed on the light receiver 51 is not affected. Thus, the fourth insulation film 81 on the light receiver 51 is formed evenly.

After each metal layer and each insulation film are stacked, an open part 55 is formed (FIG. 5F) by etching each insulation film stacked on the light receiver 51 in order to enhance incident efficiency of reflected light to the light receiver 51. Since a surface of the fourth insulation film 81 stacked on the light receiver 51 is formed evenly, the bottom surface of the open part 55 is also formed evenly. This is because that the bottom surface of the open part 55 has a form which the surface form of the film formed on the top is transcribed as it is before etching.

As described in this embodiment, when a flat layer is formed by the second insulation film 78, each insulation film stacked on the light receiver 51 is also formed evenly. Thus, the bottom surface of the open part 55 can be formed evenly and the incident efficiency within the surface of the light receiver 51 can be equalized. Furthermore, an adverse affect on the photoelectric conversion of the photodetector generated due to light reflected by an uneven portion of the bottom surface of the open part 55 can be suppressed.

As explained above, the present invention provides a method for manufacturing a semiconductor integrated circuit device comprising: on a semiconductor substrate which includes a light receiver, forming a first insulation film on the semiconductor substrate; forming a wiring structure around the light receiver on the first insulation film by the damascene process; forming a second insulation film on the wiring structure; and opening the second insulation film formed on the light receiver by etching.

Furthermore, another embodiment of the present invention provides a method for manufacturing a semiconductor integrated circuit device comprising: on a semiconductor substrate which includes a light receiver, forming a first insulation film on the semiconductor substrate; forming a wiring structure around the light receiver on the first insulation film; forming a second insulation film on the wiring structure; flattening a surface of the second insulation film; forming a third insulation film on the second insulation film; and opening the third insulation film formed on the light receiver by etching.

According to the present invention, since a bottom surface of an open part can be formed evenly, an amount of incident light within a surface of a light receiver can be equalized.

What is claimed is:

1. A method for manufacturing a semiconductor integrated circuit device comprising:
forming a light receiver in a surface of a semiconductor substrate;
forming a first insulation film on the semiconductor substrate;
forming a wiring structure around the light receiver on the first insulation film by a damascene process;
forming a second insulation film on the wiring structure;
and etching the second insulation film formed on the light receiver and forming an open part.

2. A method for manufacturing a semiconductor integrated circuit device comprising:
forming a light receiver in a surface of a semiconductor substrate;
forming a first insulation film on the semiconductor substrate;
forming a wiring structure around the light receiver on the first insulation film;
forming a second insulation film on the wiring structure;
flattening a surface of the second insulation film;
forming a third insulation film on the second insulation film;
and etching the third insulation film formed on the light receiver and forming an open part.
